(19) United States
(12) Patent Application Publication
(10) Pub. No.: US 2024/0282709 A1
(43) Pub. Date: Aug. 22, 2024

(54) Layered Substrate with Ruthenium Layer and Method for Producing

(71) Applicant: Applied Materials, Inc., Santa Clara, CA (US)

(72) Inventors: Zhaoxuan WANG, Sunnyvale, CA (US); Jianxin LEI, Fremont, CA (US); Wenting HOU, San Jose, CA (US); David Maxwell GAGE, San Jose, CA (US); Zihao HE, Fremont, CA (US)

(21) Appl. No.: 18/112,564

(22) Filed: Feb. 22, 2023

(51) Int. Cl. H01L 23/532; H01L 21/02; H01L 21/3205; H01L 21/321; H01L 21/768

(52) U.S. Cl. CPC H01L 23/53266; H01L 21/0217; H01L 21/02183; H01L 21/02186; H01L 21/02189; H01L 21/02381; H01L 21/02414; H01L 21/02631; H01L 21/32051; H01L 21/3212; H01L 21/76834; H01L 21/7684; H01L 23/5329

(57) ABSTRACT

A method to produce a layered substrate includes depositing a ruthenium layer having a first average grain size on a substrate; annealing the substrate at a temperature and for a period of time sufficient to produce an annealed ruthenium layer having a second average grain size which is greater than the first average grain size; and removing a portion of the ruthenium layer by chemical mechanical planarization to form a planarized ruthenium layer, to produce the layered substrate. A layered substrate is also disclosed.

### FIELD

Embodiments of the present disclosure generally relate to semiconductor manufacturing processes, more particularly, to processes to produce layered semiconductor substrates.

### BACKGROUND

Ruthenium (Ru) metal is useful in various layered substrate devices, such as DRAM devices. The inventors have observed, however, that Ru processing techniques can undesirably lead to several integration issues, such as high line edge roughness (LER) and/or bitline rounding. Accordingly, the inventors have provided improved methods for producing Ru films on devices.

### SUMMARY

Methods for producing a layered substate are provided herein. In embodiments, a method to produce a layered substrate, comprises depositing a ruthenium layer having a first average grain size on a substrate; annealing the substrate at a temperature and for a period of time sufficient to produce an annealed ruthenium layer having a second average grain size which is greater than the first average grain size; removing a portion of the annealed ruthenium layer by chemical mechanical planarization to form a planarized ruthenium layer, to produce the layered substrate.

In other embodiments, a layered substrate comprises a base substrate; a diffusion barrier layer disposed over the base substrate; and a ruthenium layer having a root mean square roughness of less than or equal to about 1 nm disposed over the diffusion barrier layer, wherein a ratio of an average grain size of the ruthenium layer in nanometers divided by a thickness of the ruthenium layer in nanometers, is greater than or equal to about 20.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 depicts a flow diagram of a method for producing a layered substrate in accordance with embodiments of the present disclosure.

FIG. 2A1 depicts a block diagram of a partially completed or intermediate layered substrate according to embodiments disclosed herein.

FIG. 2A2 depicts a block diagram of a partially completed or intermediate layered substrate after annealing according to embodiments disclosed herein.

FIG. 2B depicts a block diagram of a layered substrate according to embodiments disclosed herein.

FIG. 2C depicts a block diagram of a layered substrate according to other embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

In embodiments, a method to produce a layered substrate comprises depositing a ruthenium layer having a first average grain size on a substrate; annealing the substrate at a temperature and for a period of time sufficient to produce an annealed ruthenium layer having a second average grain size which is greater than the first average grain size; removing a portion of the annealed ruthenium layer by chemical mechanical planarization to form a planarized ruthenium layer, to produce the layered substrate.

In embodiments, the method further comprises depositing a capping layer comprising silicon nitride (SiN) over the planarized ruthenium layer. In embodiments, the ruthenium layer is deposited by physical vapor deposition.

In embodiments, the ruthenium layer is deposited over a diffusion barrier layer comprising at least one of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}ZrₐNₓ, wherein c+d equals an integer from 1 to 3 and x is from 1 to 5 to result in a neutral compound. In embodiments, the ruthenium layer is deposited over a molybdenum metal layer.

In embodiments of the method, a thickness of the planarized ruthenium layer is greater than or equal to about 50% of the ruthenium layer prior to the chemical mechanical planarization.

In embodiments, the annealing the substrate is at a temperature of greater than or equal to about 800° C. In embodiments, a ratio of the second average grain size of the planarized ruthenium layer in nanometers divided by a thickness of the planarized ruthenium layer in nanometers is greater than or equal to about 20. In embodiments, a maximum grain size of the planarized ruthenium layer is greater than or equal to about 200 nm. In embodiments, a root mean square roughness of the planarized ruthenium layer is less than or equal to about 1 nm.

In embodiments, a root mean square roughness of the planarized ruthenium layer is less than or equal to about 90% of a root mean square roughness of the ruthenium layer prior to planarization. In embodiments, a surface resistivity of the planarized ruthenium layer is less than or equal to about 90% of a surface resistivity of the ruthenium layer prior to annealing.

In embodiments, a layered substrate comprises a base substrate; a diffusion barrier layer disposed over the base substrate; and a ruthenium layer having a root mean square roughness of less than or equal to about 1 nm disposed over the diffusion barrier layer, wherein a ratio of an average grain size of the ruthenium layer in nanometers divided by a thickness of the ruthenium layer in nanometers, is greater than or equal to about 20.

In embodiments, the ruthenium layer has a maximum grain size of greater than or equal to about 200 nm. In embodiments, the layered substrate further comprises a capping layer disposed over the ruthenium layer. In embodiments, the capping layer comprises silicon nitride (SiN). In embodiments, the layered substrate further comprises a molybdenum layer disposed between the diffusion barrier layer and the ruthenium layer. In embodiments, the diffusion barrier layer comprises one or more of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}ZrₐNₓ, wherein c+d equals an integer from 1 to 3 and x is from 1 to 5 to result in a neutral compound.

In embodiments, the base substrate is Si. In embodiments, the base substrate comprises SiO₂.

As used herein, the terms “on”, “over”, “above,” “below,” and “between” as used herein refer to a relative position of one layer with respect to other layers. As such, one layer deposited or disposed on, over, above or below another layer may be directly in contact with the other layer or may have one or more intervening layers. Moreover, one layer deposited or disposed between layers may be directly in contact with the layers or may have one or more intervening layers. In contrast, a layer disposed in contact with another layer refers to the two layers being in direct contact with each other.

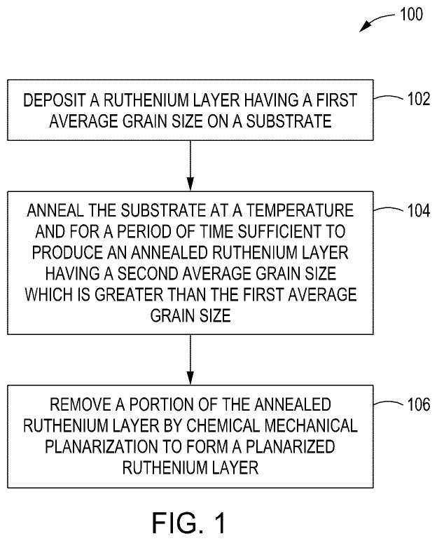

FIG. 1 is a flow chart of a process 100, according to an example of the present disclosure. According to an example, one or more process blocks of FIG. 1 may be performed by one or more substrate processing systems. The substrate processing systems can be controlled by a controller, which can include a memory or computer readable medium having the one or more process blocks of process 100 stored therein. When executed by the controller, the one or more substrate processing systems are controlled to perform one or more blocks of the process 100 as described herein.

As shown in FIG. 1, process 100 may include depositing a ruthenium layer on a base substrate having a first average grain size (block 102). For example, a device may deposit a ruthenium layer on a base substrate using physical vapor deposition, having a first average grain size, as described above. As shown in FIG. 1, process 100 may further include annealing the substrate at a temperature and for a period of time sufficient to produce an annealed ruthenium layer having a second average grain size which is greater than the first average grain size (block 104). The annealing of the substrate may be conducted by heating at a temperature, e.g., greater than or equal to about 800° C. and for a period of time sufficient to produce a plurality of grains in the ruthenium layer having a second average grain size which is greater than the first average grain size. As also shown in FIG. 1, process 100 may include removing a portion of the annealed ruthenium layer by chemical mechanical planarization (CMP) to form a planarized ruthenium layer, thereby producing the layered substrate (block 106). For example, a CMP device may be utilized to remove up to about 50% of the initial thickness of the annealed ruthenium layer by chemical mechanical planarization to form a planarized ruthenium layer, thereby producing the layered substrate. In embodiments, the process to produce the layered substrate may include additional processing both before and after the formation of the planarized ruthenium layer.

Although FIG. 1 shows example blocks of process 100, in some implementations, process 100 may include additional blocks, fewer blocks, different blocks.

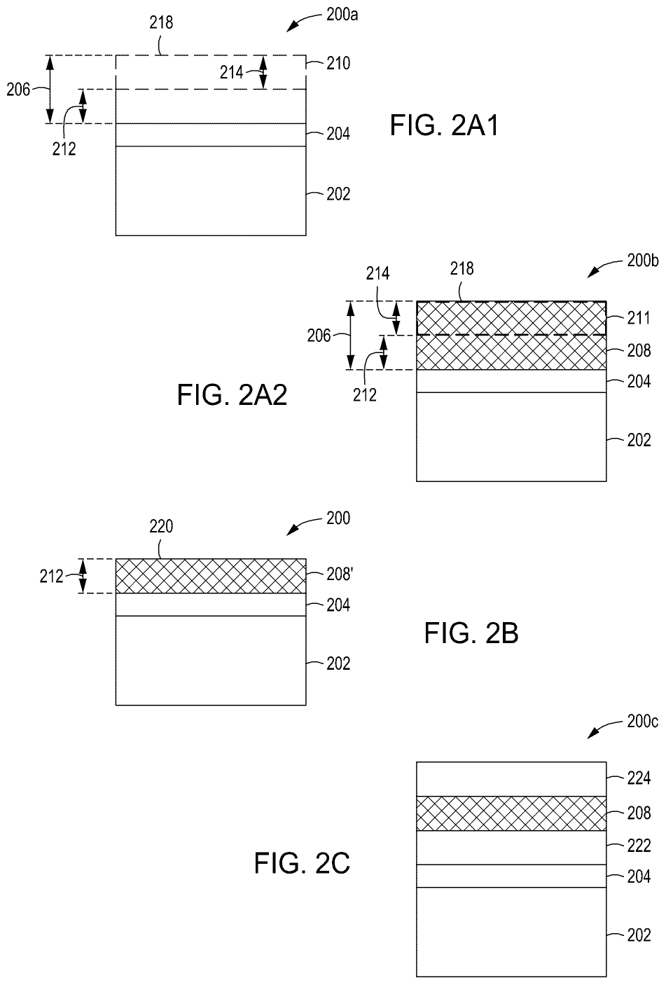

As shown in FIG. 2B, in embodiments, the layered substrate 200 may include a base substrate 202, which in embodiments may comprise silicon (Si), which in embodiments may consist essentially of Si, or may consist of Si. In other embodiments, the base substrate 202 may comprise silicon dioxide (SiO₂), or may consist essentially of SiO₂, of may consist of SiO₂.

In embodiments, a diffusion barrier layer 204 is disposed over the base substrate, which in embodiments may be disposed in contact with the base substrate 202. In embodiments, the diffusion barrier layer 204 may further enhance the adherence of a metal layer disposed upon the diffusion barrier layer 204.

In embodiments, the diffusion barrier layer 204 comprises a nitride, which in embodiments is one or more of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}ZrₐNₓ, wherein c+d equals an integer from 1 to 3 and x is from 1 to 5 to result in a neutral compound.

In embodiments the nitride layer is deposited using reactive physical vapor deposition, e.g., by sputtering a titanium or tantalum target in a nitrogen/argon plasma. The diffusion barrier layer is configured to limit the diffusion of the underlayer and/or the ruthenium layer into the semiconductor substrate and the dielectric layer, thereby dramatically increasing the reliability of the connection. In embodiments, the diffusion barrier layer has a thickness greater than or equal to about 5 Å, or greater than or equal to about 50 Å, or greater than or equal to about 100 Å, or greater than or equal to about 150 Å, and less than or equal to about 1000 Å, or less than or equal to about 500 Å, or less than or equal to about 200 Å.

In some embodiments, the diffusion barrier layer further comprises an amount of the base substrate, e.g., the diffusion barrier layer is doped with the material utilized in the base substrate in an amount effective to increase or facilitate adhesion between the diffusion barrier layer and the base substrate. In some embodiments, diffusion barrier layer further comprises less than or equal to about 1 weight percent of the material present in the base substrate material, or less than or equal to about 0.1 weight percent of the base substrate material, or less than or equal to about 0.01 weight percent of the base substrate material, based on the total amount of diffusion barrier layer present.

In embodiments, as shown in FIG. 2B, the layered substrate 200 includes a planarized ruthenium layer 208 having a final thickness 212, which may comprise ruthenium metal, may consist essentially of ruthenium metal, or which is ruthenium metal. In embodiments, any of the layers of the layered substrate including the diffusion barrier layer when present, a molybdenum layer when present, the ruthenium layer, and/or the capping layer when present, can be deposited by physical vapor deposition, plasma enhanced physical vapor deposition, chemical vapor deposition, plasma enhanced chemical vapor deposition, atomic layer deposition, and/or the like. In embodiments, at least one of the diffusion barrier layer, a molybdenum layer when present, the ruthenium layer, and/or the capping layer when present, is deposited by physical vapor deposition. In embodiments, the ruthenium layer is deposited by physical vapor deposition.

As shown in FIG. 2A1, in embodiments, an intermediate layered substrate 200a is formed into the layered substrate 200 (see FIG. 2B) having the planarized ruthenium layer 208, which is formed from a deposited ruthenium layer 210, having a first thickness 206 and a first average grain size. This intermediate layered substrate 200a is then annealed to form an annealed intermediate layered substrate 200b, comprising the annealed ruthenium layer 211 as shown in FIG. 2A2 in which the first average grain size of the deposited ruthenium layer 210 of intermediate substrate 200a is enlarged to a second average grain size present in the annealed ruthenium layer 211 of annealed intermediate substrate 200b. A portion of the annealed ruthenium layer 211 is removed by chemical mechanical planarization (CMP) to form the layered substrate 200 shown in FIG. 2B, having the planarized ruthenium layer 208 which has a final thickness 212, which is less than the deposited first thickness 206 of the deposited ruthenium layer 210.

The deposited ruthenium layer 210, when deposited, e.g., via physical vapor deposition, has a first average grain size, which is determined on the surface 218 of the intermediate layered substrate 200a, of the deposited ruthenium layer 210 before annealing. The first average grain size is enlarged to a second average grain size during annealing to form the annealed ruthenium layer 211 shown in FIG. 2A2. The annealed intermediate layered substrate 200b is then subjected to chemical mechanical planarization to form the planarized ruthenium layer 208, having a second average grain size which is determined on an upper surface 220 of the planarized ruthenium layer 208 of the layered substrate 200 (see FIG. 2B). In embodiments, the annealing is conducted at a temperature of greater than or equal to about 800° C., or equal to about 850° C., or greater than equal to about 870° C., or greater than equal to about 900° C. for a period of time sufficient to enlarge the grain size to a second average grain size. In embodiments, the annealing is conducted for greater than or equal to about 30 seconds, or greater than or equal to about 1 minute, or greater than or equal to about 5 minutes, or greater than or equal to about 10 minutes, or greater than or equal to about 60 minutes. In embodiments, the annealing is conducted in an inert atmosphere.

The inventors have observed that larger grain size in the ruthenium layer after annealing has benefits which include reduced surface resistivity and enhanced stability. However, the inventors have observed that the grain size formed by annealing of the ruthenium layer also depends on the thickness of the ruthenium layer. The larger grain sizes are only formed during the annealing process in ruthenium layers which are thicker than desired for various end uses. Ruthenium grain growth during the annealing has also been observed to cause other integration issues, such as increased roughness, bitline rounding, and the like.

The inventors have observed that after the deposited ruthenium layer 210 is deposited at a first thickness 206, and then subject to annealing to form the annealed ruthenium layer 211 to increase the grain size of the deposited ruthenium layer 210 from of first average grain size to a second average grain size, the annealing results in the annealed ruthenium layer 211 having a surface roughness which may be problematic. The addition of a CMP procedure to the annealed ruthenium layer 211 to form the planarized ruthenium layer 208 having a reduced final thickness 212, significantly reduces the roughness of the planarized ruthenium layer 208 and improves the surface resistivity of the planarized ruthenium layer 208, relative to the deposited ruthenium layer 210 prior to annealing.

In embodiments, the deposited ruthenium layer 210 is deposited at a thickness of greater than or equal to about 10 nm, or greater than or equal to about 15 nm, or greater than or equal to about 20 nm, or greater than or equal to about 25 nm, or greater than or equal to about 30 nm. The deposited ruthenium layer 210 is then annealed as described herein to form the annealed ruthenium layer 211, which is then subjected to CMP such that an amount of the annealed ruthenium layer 211 is removed, i.e., a removed thickness 214, to produce the planarized ruthenium layer 208 having a final thickness 212 after planarization.

In embodiments, the final thickness 212 of the planarized ruthenium layer 208 is greater than or equal to about 50%, or greater than or equal to about 60%, or greater than or equal to about 70%, or greater than or equal to about 80%, or greater than or equal to about 90% of the first thickness 206 of the deposited ruthenium layer 210 (after annealing), prior to the chemical mechanical planarization.

In embodiments, a ratio of the second average grain size of the planarized ruthenium layer in nanometers, determined on the planarized upper surface 220 of the planarized ruthenium layer 208, divided by the final thickness 212 of the planarized ruthenium layer 208 in nanometers, is greater than or equal to about 20, or greater than or equal to about 30, or greater than or equal to about 40, or greater than or equal to about 50. In contrast, a ratio of the first average grain size of the deposited ruthenium layer 210 in nanometers, determined on the surface 218 of the deposited ruthenium layer 210, divided by the first thickness 206 of the deposited ruthenium layer 210 in nanometers, is less than or equal to about 10, or less than or equal to about 8, or less than or equal to about 5.

In embodiments, a maximum grain size of the planarized ruthenium layer 208 is greater than or equal to about 200 nm, or greater than or equal to about 225 nm, or greater than or equal to about 250 nm, or greater than or equal to about 300 nm, or greater than or equal to about 350 nm, or greater than or equal to about 400 nm, or greater than or equal to about 550 nm. In embodiments, a root mean square roughness of the upper surface 220 of the planarized ruthenium layer 208 is less than or equal to about 1 nm, or less than or equal to about 0.8 nm, or less than or equal to about 0.5 nm. In embodiments, a root mean square roughness of the upper surface 220 of the planarized ruthenium layer 208 is less than or equal to about 90%, or less than or equal to about 80%, or less than or equal to about 70%, or less than or equal to about 60% of a root mean square roughness of the annealed ruthenium layer 211 prior to the chemical mechanical planarization.

In embodiments, a surface resistivity of the planarized ruthenium layer 208 is less than or equal to about 99%, or less than or equal to about 95%, or less than or equal to about 90%, or less than or equal to about 80% of a surface resistivity of the deposited ruthenium layer 210, when determined at the same thickness of both the deposited ruthenium layer and the planarized ruthenium layer.

Accordingly, the layered substrate according to embodiments disclosed herein has the benefits of the larger grain size only achievable using thicker ruthenium layers, with a thinner ruthenium layer having a reduced roughness obtained by the CMP procedure.

FIG. 2B shows an embodiment of the layered substrate after CMP, wherein the diffusion barrier layer 204 is deposited on, and in contact with the base substrate 202, and the planarized ruthenium layer 208 is deposited on, and in contact with the diffusion barrier layer 204.

FIG. 2C is a block diagram showing an embodiment of an alternative layered substrate 200c, wherein the planarized ruthenium layer 208 is disposed over a molybdenum layer 222, and which further comprises a capping layer 224 disposed over the planarized ruthenium layer 208. In embodiments, the capping layer 224 comprises silicon nitride, or in embodiments, is silicon nitride.

In embodiments, the process to produce the layered substrate may be performed in a substrate processing chamber which can be any PVD, CVD, ALD or other deposition chamber configured to deposit the diffusion barrier layer, the ruthenium layer, the molybdenum layer when present, and/or the capping layer. In embodiments, the annealing may take place in the same deposition chamber, or in another processing chamber.

The removal of a portion of the annealed ruthenium layer by chemical mechanical planarization to form a planarized ruthenium layer may be conducted using any assembly or system suitable for CMP to produce the layered substrate according to embodiments disclosed herein.

The methods described herein may be performed in individual process chambers that may be provided in a standalone configuration or as part of one or more cluster tools.

### Embodiments

In accordance with embodiments of the disclosure, at least the following embodiments are contemplated.
E1. A method to produce a layered substrate, comprising:
   depositing a ruthenium layer having a first average grain size on a substrate;
   annealing the substrate at a temperature and for a period of time sufficient to produce an annealed ruthenium layer having a second average grain size which is greater than the first average grain size;
      removing a portion of the annealed ruthenium layer by chemical mechanical planarization to form a planarized ruthenium layer, to produce the layered substrate.
E2. The method according to Embodiment E1, further comprising depositing a capping layer comprising silicon nitride (SiN) over the planarized ruthenium layer.
E3. The method according to Embodiments E1 through E2, wherein the ruthenium layer is deposited by physical vapor deposition.
E4. The method according to Embodiments E1 through E3, wherein the ruthenium layer is deposited over a diffusion barrier layer comprising at least one of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}ZrₐNₓ, wherein c+d equals an integer from 1 to 3 and x is from 1 to 5 to result in a neutral compound.
E5. The method according to Embodiments E1 through E4, wherein the ruthenium layer is deposited over a molybdenum layer.
E6. The method according to Embodiments E1 through E5, wherein a thickness of the planarized ruthenium layer is greater than or equal to about 50% of the annealed ruthenium layer prior to the chemical mechanical planarization.
E7. The method according to Embodiments E1 through E6, wherein the annealing the substrate is at a temperature of greater than or equal to about 800° C.
E8. The method according to Embodiments E1 through E7, wherein a ratio of the second average grain size of the planarized ruthenium layer in nanometers divided by a thickness of the planarized ruthenium layer in nanometers is greater than or equal to about 20.
E9. The method according to Embodiments E1 through E8, wherein a maximum grain size of the planarized ruthenium layer is greater than or equal to about 200 nm.
E10. The method according to Embodiments E1 through E9, wherein a root mean square roughness of the planarized ruthenium layer is less than or equal to about 1 nm.
E11. The method according to Embodiments E1 through E10, wherein a root mean square roughness of the planarized ruthenium layer is less than or equal to about 90% of a root mean square roughness of the annealed ruthenium layer prior to planarization.
E12. The method according to Embodiments E1 through E11, wherein a surface resistivity of the planarized ruthenium layer is less than or equal to about 90% of a surface resistivity of the ruthenium layer prior to annealing.
E13. A layered substrate, produced according to the method of Embodiments E1 through E12.
E14. A layered substrate, comprising:
   a ruthenium layer having a root mean square roughness of less than or equal to about 1 nm, disposed over a base substrate;
   wherein a ratio of an average grain size of the ruthenium layer in nanometers divided by a thickness of the ruthenium layer in nanometers, is greater than or equal to about 20.
E15. The layered substrate according to Embodiments E13 through E14, wherein the ruthenium layer has a maximum grain size of greater than or equal to about 200 nm.
E16. The layered substrate according to Embodiments E13 through E15, further comprising one or more of a diffusion barrier layer disposed between the base substrate and the ruthenium layer; and
a capping layer disposed over the ruthenium layer.
E17. The layered substrate according to Embodiment E16, wherein the capping layer comprises silicon nitride (SIN).
E18. The layered substrate according to Embodiments E16 through E17, wherein the diffusion barrier layer comprises one or more of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}ZrₐNₓ, wherein c+d equals an integer from 1 to 3 and x is from 1 to 5 to result in a neutral compound.
E19. The layered substrate according to Embodiments E13 through E17, further comprising a molybdenum layer disposed between the base substrate and the ruthenium layer.
E20. The layered substrate according to Embodiments E13 through E19, wherein the base substrate consists essentially of Si.
E21. The layered substrate according to Embodiments E13 through E20, wherein the base substrate comprises SiO₂.

The disclosure may be practiced using other semiconductor substrate processing systems wherein the processing parameters may be adjusted to achieve acceptable characteristics by those skilled in the art by utilizing the teachings disclosed herein without departing from the spirit of the disclosure. While the foregoing is directed to embodiments of the present disclosure, other and further embodiments of the disclosure may be devised without departing from the basic scope thereof.

1. A method to produce a layered substrate, comprising:
depositing a ruthenium layer having a first average grain size on a substrate;
annealing the substrate at a temperature and for a period of time sufficient to produce an annealed ruthenium layer having a second average grain size which is greater than the first average grain size; and
removing a portion of the annealed ruthenium layer by chemical mechanical planarization to form a planarized ruthenium layer; to produce the layered substrate.

2. The method of claim 1, further comprising depositing a capping layer comprising silicon nitride (SiN) over the planarized ruthenium layer.

3. The method of claim 1, wherein the ruthenium layer is deposited by physical vapor deposition.

4. The method of claim 1, wherein the ruthenium layer is deposited over a diffusion barrier layer comprising at least one of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}ZrₐNₓ, wherein c+d equals an integer from 1 to 3 and x is from 1 to 5 to result in a neutral compound.

5. The method of claim 1, wherein the ruthenium layer is deposited over a molybdenum layer.

6. The method of claim 1, wherein a thickness of the planarized ruthenium layer is greater than or equal to about 50% of the annealed ruthenium layer prior to the chemical mechanical planarization.

7. The method of claim 1, wherein the annealing the substrate is at a temperature of greater than or equal to about 800° C.

8. The method of claim 1, wherein a ratio of the second average grain size of the planarized ruthenium layer in nanometers divided by a thickness of the planarized ruthenium layer in nanometers is greater than or equal to about 20.

9. The method of claim 1, wherein a maximum grain size of the planarized ruthenium layer is greater than or equal to about 200 nm.

10. The method of claim 1, wherein a root mean square roughness of the planarized ruthenium layer is less than or equal to about 1 nm.

11. The method of claim 1, wherein a root mean square roughness of the planarized ruthenium layer is less than or equal to about 90% of a root mean square roughness of the annealed ruthenium layer prior to planarization.

12. The method of claim 1, wherein a surface resistivity of the planarized ruthenium layer is less than or equal to about 90% of a surface resistivity of the ruthenium layer prior to annealing.

13. A layered substrate, comprising:
a ruthenium layer having a root mean square roughness of less than or equal to about 1 nm, disposed over a base substrate, wherein a ratio of an average grain size of the ruthenium layer in nanometers divided by a thickness of the ruthenium layer in nanometers, is greater than or equal to about 20.

14. The layered substrate of claim 13, wherein the ruthenium layer has a maximum grain size of greater than or equal to about 200 nm.

15. The layered substrate of claim 13, further comprising one or more of a diffusion barrier layer disposed between the base substrate and the ruthenium layer; and
a capping layer disposed over the ruthenium layer.

16. The layered substrate of claim 15, wherein the capping layer comprises silicon nitride (SIN).

17. The layered substrate of claim 15, wherein the diffusion barrier layer comprises one or more of titanium nitride TiₐNₓ, tantalum nitride, TaₐNₓ, zirconium nitride ZrₐNₓ, wherein each a is independently from 1 to 3 and x is from 1 to 5 to result in a neutral compound; or titanium zirconium nitride Ti_{c}Zr_{d}Nₓ, wherein c+d equals an integer from 1 to 3 and x is from 1 to 5 to result in a neutral compound.

18. The layered substrate of claim 13, further comprising a molybdenum layer disposed between the base substrate and the ruthenium layer.

19. The layered substrate of claim 13, wherein the base substrate consists essentially of Si.

20. The layered substrate of claim 13, wherein the base substrate comprises SiO₂.
